(19) United States
(12) Patent Application Publication
(10) Pub. No.: US 2012/0063090 A1
(43) Pub. Date: Mar. 15, 2012

(54) COOLING MECHANISM FOR STACKED DIE PACKAGE AND METHOD OF MANUFACTURING THE SAME

(75) Inventors: Yi-Li HSIAO, Hsinchu City (TW); Chen-Hua YU, Hsinchu (TW); Da-Yuan SHIH, Hsinchu (TW); Chih-Hang TUNG, Hsinchu (TW); Chun Hui YU, Zhubei City (TW)

(73) Assignee: TAIWAN SEMICONDUCTOR MANUFACTURING COMPANY, LTD., Hsinchu (TW)

(21) Appl. No.: 12/878,319

(22) Filed: Sep. 9, 2010

(51) Int. Cl. H01L 23/34; H01L 21/50

(52) U.S. Cl. 361/699; 438/107; 257/E21.499

(57) ABSTRACT

An apparatus for cooling a stacked die package comprises a substrate, a first die above the substrate, a second die above the first die, and a housing containing the first and second dies. The housing seals the first and second dies from the environment. The apparatus further includes a cooling fluid in fluid communication with the first die and the second die to transfer the heat from the dies to the housing.

### BACKGROUND

The disclosure relates generally to stacked die packages, and more particularly, to cooling mechanisms for stacked die packages.

Recently, three-dimensional integrated circuit (3D IC) packages or stacked die packages have provided a possible solution to traditional two-dimensional (2D) ICs in overcoming the interconnect scaling barrier and for improving performance. In stacked die packages, multiple dies are stacked together using vertical through silicon vias (TSVs) where longer wire connections and inter-die input/output (I/O) pads are eliminated. The overall performance is significantly improved with faster and more power efficient inter-core communication across multiple silicon layers.

As effective as 3D IC technology is, 3D IC technology faces critical thermal management challenges. When multiple dies are stacked vertically in a package, the thermal path for the dissipation of the heat generated by the dies is limited. Stacked die packages are typically encapsulated in a material that does not dissipate heat well, and if the heat dissipation problem is not addressed, the dies may overheat during operation, leading to possible problems with transistor performance and reliability. To address the heat dissipation problem, cooling systems that use thermal via and liquid micro channels have been proposed. However, such systems are complex and expensive to implement.

### BRIEF DESCRIPTION OF DRAWINGS

The features, aspects, and advantages of the disclosure will become more fully apparent from the following detailed description, appended claims, and accompanying drawings in which:

FIG. 1 is a cross-sectional view of a stacked die package according to an embodiment of the present disclosure.

FIG. 2 is a cross-sectional view of a multi-chip system package according to an embodiment of the present disclosure.

FIG. 3 is a cross-sectional view of a different stacked die package according to an embodiment of the present disclosure.

FIG. 4 is a flowchart illustrating a method of manufacturing a stacked die package having a cooling mechanism according to an embodiment of the present disclosure.

### DETAILED DESCRIPTION

In the following description, numerous specific details are set forth to provide a thorough understanding of embodiments of the present disclosure. However, one having an ordinary skill in the art will recognize that embodiments of the disclosure can be practiced without these specific details. In some instances, well-known structures and processes have not been described in detail to avoid unnecessarily obscuring embodiments of the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

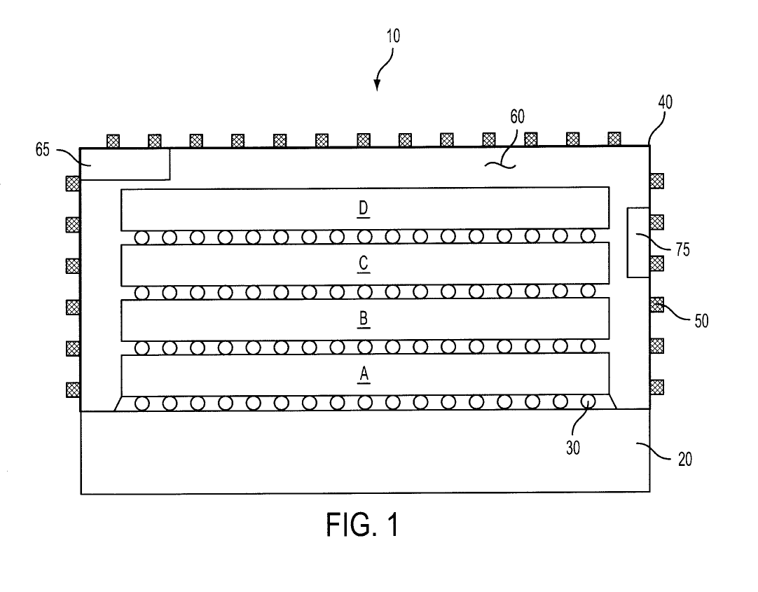

FIG. 1 is a cross-sectional view of a stacked die package 10 according to an embodiment of the present invention. Stacked die package 10 includes a substrate 20, a first die A, a second die B, a third die C, a fourth die D, a housing 40 and a cooling fluid 60 contained in a cavity of housing 40. Substrate 20 may comprise a silicon substrate although other semiconductor substrates, such as silicon-germanium substrate, III-V compound substrate, glass substrate, or silicon on insulator (SOI) substrate may be utilized in various embodiments. Dies A, B, C, and D may include one of a processor die, memory die (e.g., SRAM, DRAM), power device die, an ASIC (application specific integrated circuit) die, or other functional device dies. Dies A, B, C, and D may comprise a plurality of through silicon vias (TSVs) (not shown) for inter-die communication, silicon or other semiconductor materials and may include one or more conductive layers (not shown). There may be multiple metallization layers (not shown) formed within dies A, B, C, and D, for example, and dies A, B, C, and D may include a plurality of other layers such as inter-metal dielectric (IMD) layers (not shown). Dies A, B, C, and D may also include other active components or circuits, such as transistors, capacitors, or other such devices. Bumps 30 that sit on pads (not shown) provide electrical communication between the dies.

Although FIG. 1 shows the stacked die package 10 as having four dies A, B, C, and D stacked each upon the other, one skilled in the art will understand that the stacked die package 10 in some embodiments may have two or more dies stacked one upon the other. In some embodiments, stacked die package 10 may have more than four dies.

To address the heat dissipation problem in stacked die package 10, an approach according to an aspect of the present invention is to immerse dies A, B, C, and D in a cooling fluid. A volume of cooling fluid 60 is contained in housing 40, the housing 40 hermetically sealing dies A, B, C, and D from the environment or ambient. Cooling fluid 60 both cools and insulates dies A, B, C, and D. The cooling fluid 60 helps cool dies A, B, C, and D by absorbing heat generated by operating dies A, B, C, and D and drawing the heat away from the dies to the walls of housing 40 where the heat is then dissipated to the ambient.

Cooling fluid 60 can comprise a fluid or liquid. As an example, cooling fluid 60 can comprise a fluid such as oil, dielectric oil, water, a mixture of water and an anti-freeing agent, potassium formate, perfluorinate coolant, or the like. As a particular example, the cooling fluid 60 may comprise a non-electrically conductive liquid perfluorinate coolant such as those made by 3M™, including 3M's HFE-7100 coolant and similar such coolants.

In some embodiments, cooling fluid 60 comprises a two-phase liquid, such as which is commercially available from. One skilled in the art will understand that cooling fluid 60 may be any fluid capable of absorbing and releasing energy and may be in a fluid form, such as water, gas, oil, or a mixture thereof.

In operation a volume of cooling fluid 60 such as oil, for example heated by dies A, B, C, and D within housing 40 rises upwardly towards the top of housing 40. As the oil rises towards the top of the housing 40, upward flow is restricted and lateral flow occurs. Also, as heated oil cools, its density increases with a resultant downward flow aided by gravity. The downward flow is limited by the bottom of housing 40 consequently establishing a lateral flow to again bring the cooling fluid into engagement with the dies to begin the cycle anew. It is understood that the level of the cooling fluid should be maintained at a prescribed level as otherwise the cooling may be insufficient to lower the temperature of the operating dies.

The housing 40 defines the cooling fluid compartment and contains the cooling fluid 60. The housing 40 has a generally rectangular shape but other shapes are also contemplated; particularly, a shape or design capable of placing the cooling fluid 60 and dies A, B, C, and D in efficient heat exchange with one another. Housing 40 may be constructed of a material such as steel, aluminum, copper, silver, metal, silicon, or silicon carbide. Other materials, such as gold, though perhaps less cost effective than those already mentioned, are also thermally conductive to an adequate or even optimal degree and may also be used in certain embodiments.

To assist cooling of dies A, B, C, and D, in some embodiments an outside surface of housing 40 includes a plurality of radiators or fins 50 for heat dissipation. Fins 50 may be disposed on any or all of the outside surface(s) of housing 40. The fins 50 provide numerous surface areas for establishing heat transfer between the heated cooling fluid and the ambient air. Fins 50 may be elongated for efficient thermal energy transfer to the ambient and may be constructed of a material such as steel, aluminum, copper, silver, metal silicon, or silicon carbide. One skilled in the art will understand that fins 50 may be made from any material having a relatively high thermal conductivity. Although fins 50 as depicted in FIG. 1 are rectangular in shape, such shape is not a requirement, and fins 50 can have a shape that is square, oval, circular, or a variety of other shapes capable of assisting with heat dissipation from stacked die package 10. Fins 50 are affixed to an outer surface of housing 40 by soldering, brazing, bonding, or by some other manner.

The stacked die package 10 may also include a pressure release apparatus 65 in some embodiments. For convenience of illustration and ease of understanding, the pressure release apparatus 65 is shown in FIG. 1 simply as a box. The pressure release apparatus 65 releases pressure on the housing 40 caused by cooling fluid 60. When the temperature in the stacked die package 10 increases there is a corresponding increase in the pressure of the cooling fluid 60. If the pressure of the cooling fluid 60 is not offset, this pressure may rupture the housing 40 of the stacked die package 10. The pressure release apparatus 65 releases the pressure in cooling fluid 60 to prevent such a rupture. As one skilled in the art will understand the workings and construction of a pressure release apparatus 65, the details of such will not be described here.

In some embodiments, stacked die package 10 includes a deionizer 75 or an apparatus to deionize ions in the cooling fluid 60 that may be generated by the interaction between the cooling fluid 60 and components of the stacked die package 10, such as dies A, B, C, D, or bumps 30. If the ions are not deionized conductivity of cooling fluid 60 may increase causing shorts in one or more dies A, B, C, or D, thereby damaging them. One skilled in the art will appreciate how a deionizer is constructed and for convenience the details of such will not be described herein.

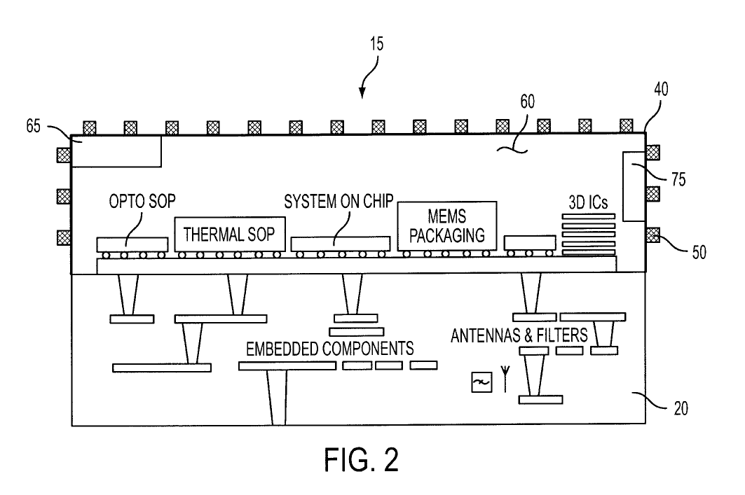

The teachings of the present disclosure of immersing stacked dies in a cooling fluid contained in a housing can also be applied to a multiple chip package. FIG. 2 is a cross-sectional view of a multi-chip system package 15 according to an embodiment of the invention. The multi-chip system package 15 may comprise many different chips, stacked chips, and components such as 3D IC packages, MEMs packaging, system on chips (SOCs), THERMAL SOPs, OPTO SOPs, embedded components, antennas and filters, and the like. A volume of cooling fluid 60 is contained in housing 40. Cooling fluid 60 both cools and insulates the components of multi-chip system package 15. The cooling fluid 60 helps cool the components by absorbing heat generated by them and drawing it to the walls of housing 40 where the heat is then dissipated to the ambient. In some embodiments, an outside surface of housing 40 includes a plurality of radiators or fins 50 for additional heat dissipation.

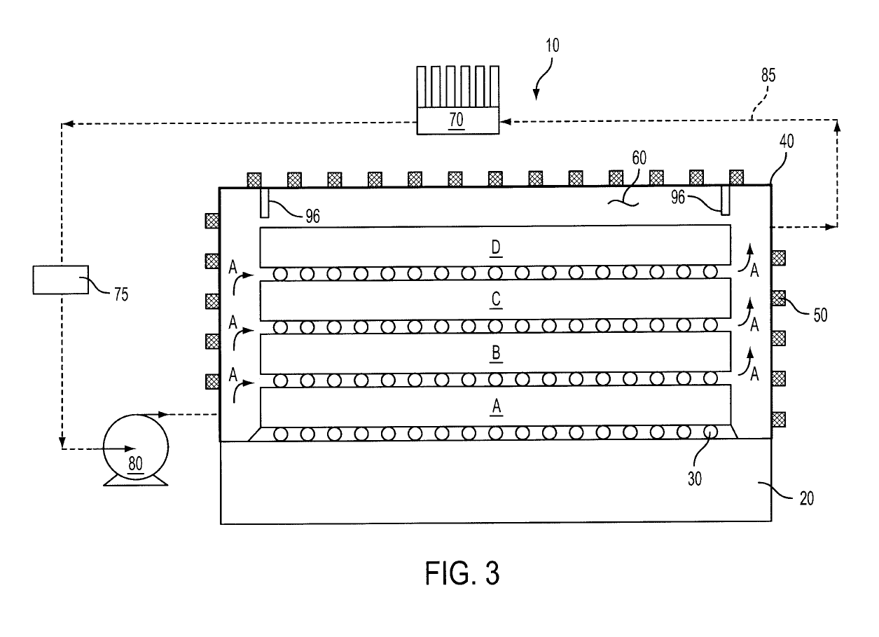

Although cooling fluid circulation within housing 40 may be achieved by passive means as described above, in another embodiment of the present invention, an active pumping action with the use of a mechanical pump 80 is employed to circulate the cooling fluid. FIG. 3 depicts the stacked die package 10 of FIG. 1 having a pump and a conduit 85. FIG. 3 does not depict a pressure release apparatus 65 for ease of illustration. One end of the conduit 85 is connected to a lower inlet or opening in housing 40 and the other end of the conduit 85 is connected to an upper outlet or opening in housing 40. The conduit can be a pipe, tube or any suitable passageway for allowing cooling fluid 60 to circulate from the upper opening to the lower opening. Pump 80 is coupled to conduit 85 for pumping the cooling fluid 60 from the upper opening to the lower opening of housing 40. Pump 80 can be any apparatus for circulating the cooling fluid by means of a piston, plunger, or a set of rotating vanes, for example. In operation, pump 80 pumps cooling fluid 60 from a bottom region of housing 40 where the cooling fluid is generally cooler to an upper region of housing 40, where the cooling fluid is generally warmer in contrast to the cooling fluid at the bottom region. The circulation of cooling fluid 60 from a lower region to an upper region of housing 40 cools dies A, B, C, and D. It is to be understood that cooling fluid flow contained within housing 40 in these embodiments and others may be circulated by gravity, active pumping action, such as with a mechanical pump as described above, passive pumping action, such as with a wicking action, thermal siphoning or the like.

In some embodiments, stacked die package 10 includes one or more barriers 96 disposed within the housing 40 of the stacked die package 10. Barriers 96 help direct the fluid flow A of cooling fluid 60, particularly to areas between two stacked dies, in the region of the bumps 30. Without barriers 96, a substantial amount of cooling fluid 60 may flow over the top of the top most die or around the sides of the dies as fluid flow will generally take the path of least resistance. One skilled in the art understands that barriers 96 may have any configuration or shape, so long as such shape or configuration directs fluid flow A substantially to regions between the dies (e.g., region of the bumps) and substantially blocks fluid flow over the top of the topmost die or around the sides of the stacked dies.

To further dissipate heat and enhance the cooling of cooling fluid 60, in another embodiment, a heat sink 70 is thermally coupled to conduit 85. Heat sink 70 draws heat from cooling fluid 60 to the ambient thereby cooling cooling fluid 60.

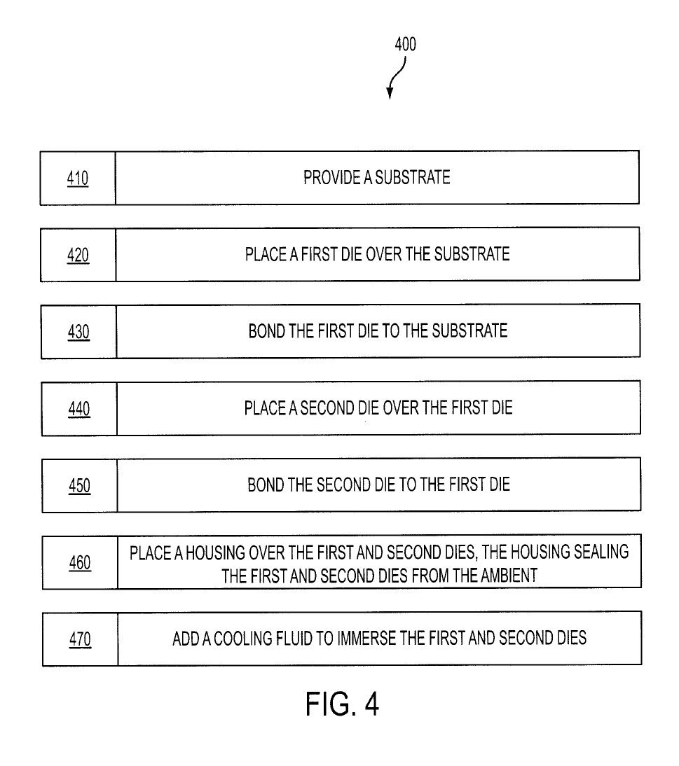

FIG. 4 is a flowchart illustrating a method 400 of manufacturing a stacked die package having a cooling mechanism according to an embodiment of the present invention. At step 410 of method 400 is to provide a substrate. At step 420 of method 400 is to place a first die over the substrate. At step 430 is to bond the first die to the substrate. As an example, the bonding of the first die to the substrate can be accomplished via a flip chip bonding process. At step 440 is to place a second die over the first die. At step 450 is to bond the second die to the first die. As an example, the bonding of the second die to the first die can be accomplished via a flip chip bonding process. At step 460 is to place a housing over the first and second dies, the housing sealing the dies. At step 470 of method 400 is to add a cooling fluid to immerse the first and second dies therein. In some embodiments, step 420 to step 450 may be replaced with a step of first bonding a first die to a second die and then placing the first die bonded to the second die over the substrate.

It is an advantage of the present invention to protect the dies in a stacked die package or chips and/or components in a multi-chip system package from excessive heat that would otherwise compromise the performance and/or reliability of the chips and/or components in these packages. It is another advantage that embodiments of the invention require minimal modifications to the current design for existing packages, is low cost and simple to implement. It is yet another advantage of the present invention that underfill materials are not needed between stacked dies (not including those dies that are disposed on a substrate or an interposer), unlike in conventional stacked die packages or multi-chip packages. It is contemplated that the cooling fluid system and method of the present disclosure can be used in any electronic packaging system, such as stacked chip package, multi-chip package, or stacked chip and multi-chip package that require a cooling fluid for cooling and/or heat prevention.

In the preceding detailed description, the present invention is described with reference to specifically exemplary embodiments thereof. It will, however, be evident that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the invention as expressed herein.

What is claimed is:

1. An apparatus for cooling a stacked die package, comprising:
a substrate;
a first die above the substrate;
a second die above the first die;
a housing containing the first and second dies, the housing sealing the first and second dies from the environment; and
a cooling fluid in fluid communication with the first die and the second die.

2. The apparatus of claim 1, wherein an outside surface of the housing comprises a plurality of fins for heat dissipation.

3. The apparatus of claim 1, wherein the housing is made from a material selected from the group consisting of aluminum, copper, silver, silicon, steel, and silicon carbide.

4. The apparatus of claim 1, wherein the cooling fluid is a liquid.

5. The apparatus of claim 1, wherein the cooling fluid is a fluid selected from the group consisting of oil, dielectric oil, water, a mixture of water and an anti-freezing agent, freon, potassium formate, and a perfluorinate coolant.

6. The apparatus of claim 1, wherein the cooling fluid is a two-phase state liquid.

7. The apparatus of claim 1, wherein the housing further includes a first opening and a second opening, the first and second openings being vertically displaced from one another, the apparatus further comprising a conduit having one end connected to the first opening and the other end connected to the second opening, the conduit for circulating the cooling liquid from the first opening to the second opening.

8. The apparatus of claim 7, further comprising a pump coupled to the conduit for pumping the cooling fluid from the first opening to the second opening.

9. The apparatus of claim 8, wherein the pump pumps the cooling fluid from a bottom region of the housing containing the first die to an upper region of the housing.

10. The apparatus of claim 7, further comprising a heat sink thermally coupled to the conduit for cooling the cooling fluid.

11. The apparatus of claim 1, further comprising an apparatus for deionizing ions in the cooling fluid.

12. The apparatus of claim 1, further comprising a pressure release apparatus for releasing pressure built-up in the housing.

13. An apparatus for cooling a multi-chip package system, comprising:
a multi-chip package having two or more dies;
a housing containing the multi-chip package, the housing sealing the multi-chip package from the environment; and
a cooling fluid in fluid communication with the two or more dies.

14. The apparatus of claim 13, wherein the multi-chip package includes a stacked die package.

15. The apparatus of claim 13, wherein an outside surface of the housing includes a plurality of fins for heat dissipation.

16. The apparatus of claim 13, wherein the cooling fluid is a fluid selected from the group consisting of oil, dielectric oil, water, a mixture of water and an anti-freezing agent, freon, potassium formate, and a perfluorinate coolant.

17. The apparatus of claim 13, wherein the cooling fluid comprises a liquid or a two-phase state liquid.

18. The apparatus of claim 13, wherein the housing further includes a first opening and a second opening, the first and second openings being vertically displaced from one another, the apparatus further comprising a conduit having one end connected to the first opening and the other end connected to the second opening, the conduit for circulating the cooling liquid from the first opening to the second opening.

19. The apparatus of claim 18, further comprising a pump coupled to the conduit for pumping the cooling fluid from the first opening to the second opening.

20. The apparatus of claim 13, further comprising an apparatus for deionizing ions in the cooling fluid.

21. The apparatus of claim 13, further comprising a pressure release apparatus for releasing pressure built-up in the housing.

22. A stacked die package comprising:
a substrate;
a first die above the substrate;
a second die above the first die;
a housing containing the first and second dies, the housing sealing the first die and the second die from the environment; and
a cooling fluid in fluid communication with the first die and the second die.

23. The stacked die package of claim 22, wherein an outside surface of the housing comprises a plurality of fins for heat dissipation.

24. The stacked die package of claim 22, wherein the cooling fluid comprises a liquid or a two-phase state liquid.

25. The stacked die package of claim 22, wherein the housing further includes a first opening and a second opening, the first and second openings being vertically displaced from one another, the apparatus further comprising a conduit having one end connected to the first opening and the other end connected to the second opening, the conduit for circulating the cooling liquid from the first opening to the second opening.

26. The stacked die package of claim 25, further comprising a pump coupled to the conduit for pumping the cooling fluid from the first opening to the second opening.

27. The stacked die package of claim 22, further comprising an apparatus for deionizing ions in the cooling fluid.

28. The stacked die package of claim 22, further comprising a pressure release apparatus for releasing pressure built-up in the housing.

29. A method of manufacturing a stacked die package, comprising:
providing a substrate;
placing a first die over the substrate;
bonding the first die to the substrate;
placing a second die over the first die;
bonding the second die to the first die;
placing a housing over the first die and the second die, the housing sealing the first die and the second die from the environment; and
adding a cooling fluid in fluid communication with the first die and the second die.

30. The method of claim 29, wherein the housing further includes a first opening and a second opening, the first and second openings being vertically displaced from one another, the apparatus further comprising a conduit having one end connected to the first opening and the other end connected to the second opening, the conduit for circulating the cooling liquid from the first opening to the second opening.

31. The method of claim 29, further comprising a pump coupled to the conduit for pumping the cooling fluid from the first opening to the second opening.

32. A method of manufacturing a stacked die package, comprising:
bonding a first die to a second die;
placing the first die bonded to the second die over the substrate;
placing a housing over the first die and the second die, the housing sealing the first die and the second die from the environment; and
adding a cooling fluid in fluid communication with the first die and the second die.
